(19) United States
(12) Patent Application Publication
(10) Pub. No.: US 2021/0095204 A1
(43) Pub. Date: Apr. 1, 2021

(54) METHOD FOR PRODUCING RARE EARTH ALUMINATE FLUORESCENT MATERIAL, RARE EARTH ALUMINATE FLUORESCENT MATERIAL, AND LIGHT EMITTING DEVICE

(71) Applicant: NICHIA CORPORATION, Anan-shi (JP)

(72) Inventors: Hiroshi Ogasa, Tokushima-shi (JP); Masato Okawa, Anan-shi (JP); Atsushi Yoshinari, Tokushima-shi (JP); Kazuya Nishimata, Anan-shi (JP)

(73) Assignee: NICHIA CORPORATION, Anan-shi (JP)

(21) Appl. No.: 17/033,881

(22) Filed: Sep. 27, 2020

(30) Foreign Application Priority Data
Sep. 27, 2019 (JP) 2019-177775

(51) Int. Cl. C09K 11/77; H01L 33/50

(52) U.S. Cl. CPC C09K 11/7774; H01L 33/502

(57) ABSTRACT

A method for producing a rare earth aluminate fluorescent material includes: subjecting a compound containing Ln that is at least one rare earth element to a first heat treatment at a temperature in a range of 1,000° C. or more and 1,600° C. or less; preparing a raw material containing an oxide containing Ln having a crystallite diameter of 1,500 Å or more obtained through the first heat treatment, a compound containing Ce, a compound containing Al, and optionally a compound containing Ga, having a chemical composition having a total molar ratio of Ln and Ce of 3, a total molar ratio of Al and Ga of a product of 5 and a parameter k of 0.95 or more and 1.05 or less, a molar ratio of Ce of a product of 3 and a parameter n of 0.005 or more and 0.050 or less, and a molar ratio of Ga of a product of a parameter m of 0 or more and 0.6 or less, the parameter k, and 5, and providing a mixture containing the raw material and a compound containing an alkaline earth metal element as a flux in an amount of 2.5% by mass or more and 7.5% by mass or less based on a total amount of the raw material; and subjecting the mixture to a second heat treatment at a temperature in a range of 1,400° C. or more and 1,800° C. or less to provide a calcined product.

### CROSS-REFERENCE TO RELATED PATENT APPLICATION

This application claims priority to Japanese Patent Application No. 2019-177775, filed on Sep. 27, 2019, the entire disclosure of which is hereby incorporated by reference in its entirety.

### BACKGROUND

### Technical Field

The present disclosure relates to a method for producing a rare earth aluminate fluorescent material, a rare earth aluminate fluorescent material, and a light emitting device. In this specification, the “fluorescent material” is used in the same meaning as a “fluorescent phosphor”.

### Description of Related Art

A light emitting device including a light emitting element, such as a light emitting diode (which may be hereinafter referred to as an “LED”) and a laser diode (which may be hereinafter referred to as an “LD”), and a fluorescent material has been used in a wide range of fields including a light emitting device for an automobile or interior illumination, a backlight source of a liquid crystal display device, and a light source device for an illumination and a projector. Examples of the known fluorescent material used in the light emitting device include a rare earth aluminate fluorescent material, such as a yttrium-aluminum-garnet fluorescent material (which may be hereinafter referred to as a “YAG fluorescent material”) containing yttrium and a lutetium-aluminum-garnet fluorescent material (which may be hereinafter referred to as a “LuAG fluorescent material”) containing lutetium.

For example, the light emitting device described in Japanese Unexamined Patent Publication No. 2015-138168 uses a rare earth aluminate fluorescent material activated with Ce that emits light in yellow to green colors.

### SUMMARY

The description herein is to provide a method for producing a rare earth aluminate fluorescent material that has a higher light emission intensity, a rare earth aluminate fluorescent material, and a light emitting device.

The description herein encompasses at least the following embodiments.

A first embodiment relates to a method for producing a rare earth aluminate fluorescent material, including:

subjecting a compound containing Ln that is at least one rare earth element selected from the group consisting of Y, La, Lu, Gd, and Tb, to a first heat treatment at a temperature in a range of 1,000° C. or more and 1,600° C. or less;

preparing a raw material containing an oxide containing Ln having a crystallite diameter of 1,500 Å or more obtained through the first heat treatment, a compound containing Ce, a compound containing Al, and optionally a compound containing Ga, having a chemical composition having a total molar ratio of Ln and Ce of 3, a total molar ratio of Al and Ga of a product of 5 and a parameter k of 0.95 or more and 1.05 or less, a molar ratio of Ce of a product of 3 and a parameter n of 0.005 or more and 0.050 or less, and a molar ratio of Ga of a product of a parameter m of 0 or more and 0.6 or less, the parameter k, and 5;

providing a mixture containing the raw material and a compound containing at least one element selected from the group consisting of Ba, Sr, Ca, Mg, and Mn as a flux in an amount of 2.5% by mass or more and 7.5% by mass or less based on a total amount of the raw material; and subjecting the mixture to a second heat treatment at a temperature in a range of 1,400° C. or more and 1,800° C. or less to provide a calcined product.

A second embodiment relates to a rare earth aluminate fluorescent material containing Ln that is at least one rare earth element selected from the group consisting of Y, La, Lu, Gd, and Tb, Ce, Al, O, and optionally Ga; having a chemical composition having a total molar ratio of Ln and Ce of 3, a molar ratio of Ce of a product of 3 and a parameter n of 0.005 or more and 0.050 or less, a total molar ratio of Al and Ga of a product of 5 and a parameter k of 0.95 or more and 1.05 or less, a molar ratio of Ga of a product of a parameter m of 0 or more and 0.6 or less, 5, and the parameter k, and a molar ratio of O of 12, per 1 mol of the chemical composition; having a cumulative 50% particle diameter Dm2 in a volume based particle size distribution measured by a laser diffraction scattering particle size distribution measuring method in a range of 23 μm or more and 50 μm or less; and having a particle diameter ratio Dm2/Db of the cumulative 50% particle diameter Dm2 to an average particle diameter Db measured by a Fisher sub-sieve sizer method of 1.2 or less.

A third embodiment relates to a light emitting device including the rare earth aluminate fluorescent material and a light emitting element having a light emission peak wavelength in a range of 380 nm or more and 485 nm or less.

According to the present disclosure, a method for producing a rare earth aluminate fluorescent material that has a high light emission intensity, a rare earth aluminate fluorescent material, and a light emitting device can be provided.

### DETAILED DESCRIPTION

The method for producing a rare earth aluminate fluorescent material, the rare earth aluminate fluorescent material, and the light emitting device according to the present disclosure will be described with reference to embodiments. The embodiments described below are examples for substantiating the technical idea of the present disclosure, and the present disclosure is not limited to the method for producing a rare earth aluminate fluorescent material, the rare earth aluminate fluorescent material, and the light emitting device shown below. The relationship between the color name and the chromaticity coordinate, the relationship between the wavelength range of light and the color name of monochromic light, and the like are in accordance with JIS Z8110.

### Method for Producing Rare Earth Aluminate Fluorescent Material

The method for producing a rare earth aluminate fluorescent material, includes: subjecting a compound containing Ln that is at least one rare earth element selected from the group consisting of Y, La, Lu, Gd, and Tb, to a first heat treatment at a temperature in a range of 1,000° C. or more and 1,600° C. or less; preparing a raw material containing an oxide containing Ln having a crystallite diameter of 1,500 Å or more obtained through the first heat treatment, a compound containing Ce, a compound containing Al, and optionally a compound containing Ga, having a chemical composition having a total molar ratio of the rare earth element Ln and Ce of 3, a total molar ratio of Al and Ga of a product of 5 and a parameter k of 0.95 or more and 1.05 or less, a molar ratio of Ce of a product of 3 and a parameter n of 0.005 or more and 0.050 or less, and a molar ratio of Ga of a product of a parameter m of 0 or more and 0.6 or less, the parameter k, and 5, and providing a mixture containing the raw material and a compound containing at least one element selected from the group consisting of Ba, Sr, Ca, Mg, and Mn as a flux in an amount of 2.5% by mass or more and 7.5% by mass or less based on the total amount of the raw material; and subjecting the mixture to a second heat treatment at a temperature in a range of 1,400° C. or more and 1,800° C. or less to provide a calcined product.

### Oxide Containing Rare Earth Element Ln

The compound containing Ln that is at least one rare earth element selected from the group consisting of Y, La, Lu, Gd, and Tb is preferably a compound that provides an oxide containing Ln through the first heat treatment at a temperature in a range of 1,000° C. or more and 1,600° C. or less. Examples of the compound containing Ln include an oxide and a metal salt containing Ln. Specific examples of the oxide containing Ln include Y₂O₃, La₂O₃, Lu₂O₃, Gd₂O₃, and Tb₄O₇. Examples of the metal salt containing Ln include an oxalate, a carbonate, a chloride, a nitrate, and a sulfate. Specific examples of the metal salt containing Ln include YCl₃, Y₂(C₂O₄)₃, Y₂(CO₃)₃, Y(NO₃)₃, Y₂(SO₄)₃, LaCl₃, La₂(C₂O₄)₃, La₂(CO₃)₃, La(NO₃)₃, La₂(SO₄)₃, LuCl₃, Lu₂(C₂O₄)₃, Lu(NO₃)₃, Lu₂(SO₄)₃, GdCl₃, and TbCl₃. The compound containing a rare earth element Ln before subjecting to the first heat treatment is preferably an oxide, for providing the oxide through the first heat treatment at a temperature in a range of 1,000° C. or more and 1,600° C. or less of the compound containing Ln. Ln preferably contains at least one kind selected from the group consisting of Y, Lu, and Tb, more preferably contains at least one kind selected from the group consisting of Y and Lu, and further preferably contains Y. In the case where Ln contains Y, the rare earth aluminate fluorescent material that has a light emission spectrum including yellow can be obtained.

### First Heat-Treatment

The compound containing Ln is subjected to the first heat treatment in a range of 1,000° C. or more and 1,600° C. or less, and thereby an oxide containing Ln having a crystallite diameter of 1,500 Å or more is obtained. It is estimated that first heat treatment in a range of 1,000° C. or more and 1,600° C. or less performed for the compound containing a rare earth element Ln increases the crystallite diameter of the resulting oxide containing Ln to 1,500 Å or more, also increases the particle diameter, and stabilizes the crystal structure. While the mechanism is not clear, the rare earth aluminate fluorescent material having a large particle diameter is obtained in the case where the rare earth aluminate fluorescent material is formed by using, as the raw material, an oxide containing Ln having a crystallite diameter of 1,500 Å or more obtained through the first heat treatment of a compound containing Ln at a temperature in a range of 1,000° C. or more and 1,600° C. or less. In the case where the rare earth aluminate fluorescent material is formed by subjecting a mixture obtained by mixing the oxide containing a rare earth element Ln having been subjected to the first heat treatment with the other raw materials to the second heat treatment to form the rare earth aluminate fluorescent material, it is estimated that the oxide containing Ln having a stable crystal structure is readily reacted with the other raw materials to stabilize the crystal structure of the resulting rare earth aluminate fluorescent material, and thereby the particle diameter of the rare earth aluminate fluorescent material is increased. In the case where a rare earth aluminate fluorescent material has a chemical composition containing Ga, there has been a tendency that since Ga tends to scatter at a high temperature of 1,000° C. or more, and readily scatters particularly in a reducing atmosphere at 1,000° C. or more, a rare earth aluminate fluorescent material having the target chemical composition is difficult to obtain, and the particle diameter of the resulting rare earth aluminate fluorescent material is decreased. There has been a significant tendency that with a larger amount of Ga contained in the rare earth aluminate fluorescent material, it is more difficult to obtain the rare earth aluminate fluorescent material having the target chemical composition, and the particle diameter of the resulting rare earth aluminate fluorescent material becomes smaller. The rare earth aluminate fluorescent material that is obtained by using, as the raw material, an oxide containing Ln obtained through the first heat treatment in a range of 1,000° C. or more and 1,600° C. or less can be a rare earth aluminate fluorescent material having a large particle diameter even though the chemical composition thereof contains Ga.

The temperature at which the first heat treatment of the compound containing Ln is performed may be in a range of 1,000° C. or more and 1,600° C. or less, and preferably in a range of 1,200° C. or more and 1,500° C. or less. In the case where the temperature for subjecting the compound containing Ln to the first heat treatment is in a range of 1,000° C. or more and 1,600° C. or less, the oxide containing Ln that has a stable crystal structure and has a crystallite diameter of 1,500 Å or more can be obtained.

Regarding the period of time of subjecting the compound containing Ln to the first heat treatment, retaining is preferably performed for 4 hours or more after reaching the temperature of the first heat treatment, for stabilizing the crystal structure of the resulting oxide. In the first heat treatment, it is preferred that the temperature is increased at a rate in a range of 3° C./min or more and 7° C./min or less to reach the temperature of the first heat treatment, and then heating is performed at the temperature of the first heat treatment for a period of 4 hours or more and less than 20 hours from the time when reaching the temperature of the first heat treatment.

The atmosphere in which the compound containing Ln is subjected to the first heat treatment may be an inert gas atmosphere including an inert gas, such as argon, helium, or nitrogen, or may be an acidic atmosphere, such as the air. In the case where the compound containing Ln is an oxide and is subjected to the first heat treatment in an inert gas atmosphere, the inert gas atmosphere may contain oxygen, and the concentration of oxygen in the inert gas atmosphere may be 10% by volume or less. The pressure of the atmosphere of the first heat treatment may be the atmospheric pressure, under which the compound containing Ln may be subjected to the first heat treatment without pressurization.

The crystallite diameter of the compound containing Ln obtained through the first heat treatment may be 1,500 Å or more, preferably in a range of 1,500 Å or more and 3,500 Å or less, more preferably in a range of 2,000 Å or more and 3,500 Å or less, and further preferably in a range of 2,500 Å or more and 3,500 Å or less. In the case where the crystallite diameter of the compound containing Ln obtained through the first heat treatment is 1,500 Å or more, the oxide containing Ln having a stable crystal structure can be used as the raw material, and the rare earth aluminate fluorescent material having a large particle diameter can be obtained. The crystallite diameter means the size of an aggregate that is assumed to be a single crystal. A larger value of the crystallite diameter means better crystallinity. The oxide containing Ln obtained through the first heat treatment of the compound containing Ln at a temperature in a range of 1,000° C. or more and 1,600° C. or less has a large crystallite diameter of 1,500 Å or more and has a stable crystal structure, and therefore it is estimated that in the case where the oxide is used as the raw material of the rare earth aluminate fluorescent material, the rare earth aluminate fluorescent material having a stable crystal structure can be obtained. In the case where the crystallite diameter of the oxide containing Ln used as the raw material is too large, it may be difficult to obtain the fluorescent material having a large particle diameter due to the decrease in reactivity in some cases.

The crystallite diameter is a value that is measured in the following manner.

A specimen is measured for an XRD (X-ray diffraction) pattern with an X-ray diffractometer.

The diffraction peak shape is calculated by using an analysis software using the fundamental parameter method, which enables quantitative analysis from the physical universal constants without the use of standard specimen, and the XRD pattern of the crystal structure model is simulated by using the database of ICDD (International Center for Diffraction Data).

The XRD pattern obtained by measuring the specimen and the XRD pattern obtained from the crystal structure model are fitted to each other, and the crystallite diameter of the specimen is measured from the value obtained by using the Rietveld method, which is optimized by the least square method minimizing the residual error. In the case where the oxide containing Ln is yttrium oxide, ICDD card No. 01-089-05592 may be used as the data for yttrium oxide. ICDD card No. 01-071-0255 may be used depending on necessity as the data for a single phase of Y₃Al₅O₁₂.

The cumulative 50% particle diameter Dm1 of the oxide containing Ln obtained through the first heat treatment in a volume based particle size distribution measured by a laser diffraction scattering particle size distribution measuring method may be preferably 6.5 μm or more, more preferably 7.5 μm or more, and further preferably 8.5 μm or more, and may be 30 μm or less. In the case where the particle diameter Dm1 of the oxide containing Ln obtained through the first heat treatment is 6.5 μm or more, the oxide containing Ln having a stable crystal structure can be used as the raw material, and the rare earth aluminate fluorescent material having a large particle diameter can be obtained. Although the oxide containing Ln obtained through the first heat treatment may smaller than the oxide containing Ln that is not subjected to the first heat treatment in some cases, the crystal structure of the oxide containing Ln used as the raw material is stabilized, and the rare earth aluminate fluorescent material having a large particle diameter is obtained, as far as the cumulative 50% particle diameter Dm 1 is 6.5 μm or more, and the crystallite diameter is 1,500 Å or more. The cumulative 50% particle diameters Dm1 and Dm2 in the volume based particle size distribution measured by the laser diffraction scattering particle size distribution measuring method may be measured, for example, by using a laser diffraction particle size distribution measurement apparatus (Mastersizer 3000, manufactured by Malvern Panalytical, Ltd.).

The BET specific surface area of the oxide containing Ln obtained through the first heat treatment is preferably in a range of 0.5 m²/g or more and 2.1 m²/g or less, more preferably in a range of 0.6 m²/g or more and 2.0 m²/g or less, further preferably in a range of 0.7 m²/g or more and 1.8 m²/g or less, and particularly preferably in a range of 0.7 m²/g or more and 1.5 m²/g or less. In the case where the BET specific surface area of the oxide containing Ln obtained through the first heat treatment is in a range of 0.5 m²/g or more and 2.1 m²/g or less, the oxide containing Ln having a stable crystal structure is readily brought into contact with the powder as the other raw materials, resulting in good reactivity, and thus the fluorescent material having a large particle diameter can be obtained. The BET specific surface area may be measured by the BET method, for example, with an automatic surface area measurement apparatus.

### Raw Materials Other Than Oxide Containing Rare Earth Element Ln Obtained Through First Heat Treatment

The raw materials of the rare earth aluminate fluorescent material other than the oxide containing Ln obtained through the first heat treatment may include a compound containing Ce, a compound containing Al, and optionally a compound containing Ga. These compounds and the oxide containing Ln obtained through the first heat treatment are prepared as the raw materials and mixed to control the rare earth elements Ln, Ce, Al, and optionally Ga contained in the raw materials to the particular molar ratios.

Examples of the compound containing Ce, the compound containing Al, and the compound containing Ga optionally used include an oxide and a metal salt. Examples of the metal salt include an oxalate, a carbonate, a chloride, a nitrate, and a sulfate. The compound used as the raw material may be in the form of a hydrate. For providing the rare earth aluminate fluorescent material having the target chemical composition, the compound containing Ce, the compound containing Al, and the compound containing Ga used optionally each are preferably an oxide. Specific examples of the oxide include CeO₂, Al₂O₃, Ga₂O₃, and Sc₂O₃. Specific examples of the metal salt include CeCl₃, Ce₂(SO₄)₃, AlCl₃, Al(NO₃)₃, Al₂(SO₄)₃, GaCl₃, and Ga(NO₃)₃.

### Mixture

As for the mixture, the raw materials are prepared and mixed has a chemical composition, in terms of a charged composition thereof, having a total molar ratio of the rare earth element Ln and Ce of 3, a total molar ratio of Al and Ga of a product of a parameter k of 0.95 or more and 1.05 or less and 5, a molar ratio of Ce of a product of a parameter n of 0.005 or more and 0.050 or less and 3, and a molar ratio of Ga of a product of a parameter m of 0 or more and 0.6 or less, the parameter k, and 5. The parameter n is preferably a value in a range of 0.008 or more and 0.045 or less, and more preferably a value in a range of 0.009 or more and 0.040 or less.

While the chemical composition of the resulting rare earth aluminate fluorescent material may not contain Ga, the rare earth aluminate fluorescent material having a large particle diameter can be obtained by using the oxide containing Ln obtained through the first heat treatment as the raw material even in the case where the mixture contains Ga, which tends to scatter in the heat treatment described later. In the case where the chemical composition of the rare earth aluminate fluorescent material contains Ga, the parameter m is preferably 0.05 or more and 0.6 or less in terms of the charged composition. The mixture may not contain the compound containing Ga.

As for the mixture, the raw materials are preferably mixed to satisfy the following formula (I) in terms of the charged composition.

(Ln₁₋ₙCeₙ)₃(Al₁₋ₘGaₘ)₅ₖO₁₂ (I)

In the formula (I), Ln represents at least one rare earth element selected from the group consisting of Y, La, Lu, Gd, and Tb, and k, m, and n satisfy 0.95≤k≤1.05, 0≤m≤0.6, and 0.005≤n≤0.050, respectively. In the formula (I), m preferably satisfies 0.05≤m≤0.6, more preferably 0.1≤m≤0.5, and further preferably 0.2≤m≤0.4. The mixture that contains the raw materials mixed to satisfy the formula (I) in terms of the charged composition can provide the rare earth aluminate fluorescent material having the target light emission peak wavelength and a large particle diameter.

### Flux

The mixture contains a compound containing at least one element selected from the group consisting of Ba, Sr, Ca, Mg, and Mn as a flux in an amount of 2.5% by mass or more and 7.5% by mass or less based on the total amount of the raw materials. The raw material specifically refers to the oxide containing Ln having a crystallite diameter of 1,500 Å or more obtained through the first heat treatment, the compound containing Ce, the compound containing Al, and optionally the compound containing Ga, but the flux is not included in the raw material. In the case where the flux is contained in the mixture in addition to the raw materials, the reaction among the raw materials is accelerated to promote the solid state reaction thereof proceeding more uniformly. It is considered that the reaction is accelerated since the temperature for providing the calcined product through the second heat treatment of the mixture is substantially the same as the formation temperature of the liquid phase of the compound used as the flux, or is higher than the formation temperature. In the case where the mixture contains the compound containing at least one element selected from the group consisting of Ba, Sr, Ca, Mg, and Mn as the flux in an amount of 2.5% by mass or more and 7.5% by mass or less based on the total amount of the raw material, the reaction of the oxide containing Ln obtained through the first heat treatment and the other raw materials can proceed uniformly, and the rare earth aluminate fluorescent material having a large particle diameter can be obtained. In the case where the amount of the flux contained in the mixture is too large, the progress of the solid state reaction may fluctuate in some cases, and the particle diameter of the resulting rare earth aluminate fluorescent material may be rather decreased in some cases.

The compound containing at least one element selected from the group consisting of Ba, Sr, Ca, Mg, and Mn used as the flux is preferably a halide. The compound used as the flux is preferably a fluoride and/or a chloride, and more preferably a fluoride, among halides. The compound used as the flux is further preferably BaF₂ since the use of BaF₂ as the flux can stabilize the garnet crystal structure of the rare earth aluminate fluorescent material, so as to promote the formation of the chemical composition of the garnet crystal structure. The content of the compound as the flux may be in a range of 2.5% by mass or more and 7.5% by mass or less, and preferably 3% by mass or more and 7% by mass or less, based on the total amount of the raw materials as 100% by mass to provide a mixture. In the case where the content of the flux in the mixture is in the range, the reaction of the oxide containing Ln obtained through the first heat treatment and the other raw materials is accelerated to achieve the solid state reaction proceeding more uniformly, and the crystal structure of the resulting rare earth aluminate fluorescent material is stabilized even in the case where Ga is contained, resulting in the rare earth aluminate fluorescent material having the target chemical composition, a large particle diameter, and a high light emission intensity.

The mixture may be provided in such a manner that the raw materials are weighed to make the target charged composition, and the compound as the flux is weighed to make the amount of the flux based on the total amount of the raw materials within the range, so as to provide the raw material, which may be then pulverized and mixed with a dry pulverizer, such as a ball mill, a vibration mill, a hammer mill, a roll mill, or a jet mill, may be pulverized and mixed with a mortar and a pestle, may be mixed with a mixer, such as a ribbon blender, a Henschel mixer, or a V-blender, or may be pulverized and mixed by using both the dry pulverizer and the mixer. The mixing operation may be dry mixing or wet mixing with a solvent added. The mixing operation is preferably dry mixing since dry mixing can shorten the process time as compared to wet mixing, resulting in the enhancement of the productivity.

### Second Heat Treatment

The mixture may be subjected to the second heat treatment after disposing the mixture on a crucible or a boat formed of a carbonaceous material, such as graphite, boron nitride (BN), aluminum oxide (alumina), tungsten (W), or molybdenum (Mo). The second heat treatment may be performed, for example, by using an electric furnace or a gas furnace.

The temperature at which the second heat treatment is performed may be in a range of 1,400° C. or more and 1,800° C. or less, preferably in a range of 1,450° C. or more and 1,700° C. or less, and more preferably in a range of 1,450° C. or more and 1,650° C. or less, for stabilizing the crystal structure of the resulting calcined product to provide the calcined product having a large particle diameter.

The second heat treatment time may vary depending on the temperature raise rate, the second heat treatment atmosphere, and the retention time at the second heat treatment temperature after reaching the second heat treatment temperature is preferably 1 hour or more, more preferably 3 hours or more, and further preferably 5 hours or more, and is preferably 20 hours or less, more preferably 18 hours or less, and further preferably 15 hours or less. Regarding the second heat treatment time, the retention time at the second heat treatment temperature after reaching the second heat treatment temperature is preferably 5 hours or more and 20 hours or less, and more preferably 8 hours or more and 15 hours or less.

The second heat treatment atmosphere is preferably a reducing atmosphere. The second heat treatment may be performed in a reducing atmosphere containing nitrogen and at least one kind of hydrogen, a compound having reducing capability, and ammonia. The reactivity of the mixture is enhanced in an atmosphere having high reducing capability, and the calcined product can be obtained by calcining under the atmospheric pressure without pressurization. The mixture is calcined through the second heat treatment in an atmosphere having high reducing capability, and thereby tetravalent Ce (Ce⁴⁺) is reduced to trivalent Ce (Ce³⁺), resulting in the calcined product having an increased proportion of trivalent Ce contributing to the light emission occupied in the calcined product. The resulting calcined product is the rare earth aluminate fluorescent material, and the calcined product can be directly used as a rare earth aluminate fluorescent material, and can be used as a rare earth aluminate fluorescent material after subjecting to the dispersion treatment and/or the acid cleaning treatment described later. In the case where the second heat treatment is performed in a reducing atmosphere, and the chemical composition of the resulting rare earth aluminate fluorescent material contains Ga, Ga contained in the compound containing Ga tends to scatter, and it may be difficult to provide the rare earth aluminate fluorescent material having a large particle diameter in some cases. In the case where the oxide containing Ln having a crystallite diameter of 1,500 Å or more obtained through the first heat treatment is used, the crystal growth is accelerated, and Ga is prevented from scattering even though the second heat treatment is performed at a relative low temperature in a range of 1,400° C. or more and 1,800° C. or less, thereby resulting in the rare earth aluminate fluorescent material that has a stable crystal structure, has the target chemical composition, has a large particle diameter, and has a high light emission intensity.

### Dispersion Treatment

The resulting calcined product is preferably subjected to a dispersion treatment including wet dispersing, wet sieving, and sedimentation classification. Specifically, it is preferred that the resulting calcined product is subjected to wet dispersing and wet sieving to remove coarse particles, and then subjected to sedimentation classification to remove fine particles. The sedimentation classification may be performed twice or more, and the number of times of the sedimentation classification is preferably 20 or less from the standpoint of the enhancement of the productivity. The particle size of the resulting calcined product can be uniformized through the dispersion treatment. Water may be used as the aqueous medium used for the wet dispersing. A dispersion medium such as alumina balls or zirconia balls may be used in the wet dispersing. The period of time of the wet dispersing is preferably 4 hours or more and 50 hours or less, and more preferably 5 hours or more and 40 hours or less, in consideration of the productivity.

### Acid Cleaning Treatment

The resulting calcined product is preferably subjected to an acid cleaning treatment. The calcined product is preferably subjected to an acid cleaning treatment after subjecting to the dispersion treatment. The impurities attached to the surface of the calcined product are removed through the acid cleaning treatment. For the acid cleaning, a hydrochloric acid aqueous solution is preferably used in consideration of the availability and the inexpensiveness thereof. The concentration of hydrochloric acid contained in the hydrochloric acid aqueous solution is preferably such a concentration that removes the impurities on the surface and does not affect the crystal structure of the calcined product, and is preferably in a range of 1% by mass or more and 20% by mass or less, and more preferably in a range of 5% by mass or more and 18% by mass or less.

The calcined product obtained by the aforementioned production method is a rare earth aluminate fluorescent material, and the resulting rare earth aluminate fluorescent material preferably has a chemical composition represented by the following formula (I).

(Ln₁₋ₙCeₙ)₃(Al₁₋ₘGaₘ)₅ₖO₁₂ (I)

In the formula (I), Ln represents at least one rare earth element selected from the group consisting of Y, La, Lu, Gd, and Tb, and k, m, and n satisfy 0.95≤k≤1.05, 0≤m≤0.6, and 0.005≤n≤0.050, respectively. In the formula (I), m preferably satisfies 0.05≤m≤0.6. The rare earth aluminate fluorescent material that has the target chemical composition, the target light emission peak wavelength, and a large particle diameter can be obtained even in the case where the chemical composition contains Ga.

### Rare Earth Aluminate Fluorescent Material

The rare earth aluminate fluorescent material may contain Ln that is at least one rare earth element selected from the group consisting of Y, La, Lu, Gd, and Tb, Ce, Al, O, and optionally Ga; may have a chemical composition having a total molar ratio of the rare earth element Ln and Ce of 3, a molar ratio of Ce of a product of a parameter n of 0.005 or more and 0.050 or less and 3, a total molar ratio of Al and Ga of a product of a parameter k of 0.95 or more and 1.05 or less and 5, a molar ratio of Ga of a product of a parameter m of 0 or more and 0.6 or less, 5, and the parameter k, and a molar ratio of O of 12, per 1 mol of the chemical composition; may have a 50% cumulative particle diameter Dm2 in a volume based particle size distribution measured by a laser diffraction scattering particle size distribution measuring method in a range of 23 μm or more and 50 μm or less; and may have a particle diameter ratio Dm2/Db of the 50% cumulative particle diameter Dm2 to an average particle diameter Db measured by a Fisher sub-sieve sizer method of 1.20 or less. The rare earth aluminate fluorescent material is preferably produced by the method for producing a rare earth aluminate fluorescent material described above, and is preferably produced by using, as a raw material, the oxide containing Ln having a crystallite diameter of 1,500 Å or more obtained through the first heat treatment at a temperature in a range of 1,000° C. or more and 1,600° C. or less.

The rare earth aluminate fluorescent material preferably has a chemical composition represented by the formula (I). Ce in the rare earth aluminate fluorescent material is an activating element, and the molar ratio of Ce per 1 mol of the chemical composition is represented by the product of the parameter n and 3. For providing the target peak wavelength and the light emission intensity of the rare earth aluminate fluorescent material, the parameter n is preferably a value in a range of 0.005 or more and 0.050 or less (0.005≤n≤0.050), more preferably in a range of 0.008 or more and 0.045 or less (0.008≤n≤0.045), and further preferably in a range of 0.009 or more and 0.040 or less (0.009≤n≤0.040).

The rare earth element Ln in the chemical composition of the rare earth aluminate fluorescent material is an element constituting the crystal structure of the garnet structure with Al and Ga depending on necessity. The rare earth element Ln preferably contains at least one kind selected from the group consisting of Y, Lu, and Tb, and more preferably contains at least one kind selected from the group consisting of Y and Lu. In the chemical composition of the rare earth aluminate fluorescent material, the rare earth element Ln that contains Y can provide a light emission spectrum including yellow color.

In the chemical composition of the rare earth aluminate fluorescent material, Ga contained depending on necessity may form the crystal skeleton of the garnet structure with Al. In the chemical composition of the rare earth aluminate fluorescent material, the molar ratio of Ga is represented by the product of the parameter m of 0 or more and 0.6 or less, the parameter k of 0.95 or more and 1.05 or less, and 5. For providing the stability of the crystal structure and the target light emission spectrum of the rare earth aluminate fluorescent material, the parameter m is in a range of 0 or more and 0.6 or less (0≤m≤0.6), and may be in a range of 0.02 or more and 0.6 or less (0.02≤m≤0.6), in a range of 0.05 or more and 0.6 or less (0.05≤m≤0.6), in a range of 0.1 or more and 0.5 or less (0.1≤m≤0.5), or in a range of 0.2 or more and 0.4 or less (0.2≤m≤0.4).

In the chemical composition of the rare earth aluminate fluorescent material, the parameter k is the coefficient of the total molar ratio of Al and Ga, i.e., 5, and in the chemical composition of the rare earth aluminate fluorescent material, there are cases where the total molar ratio of Al and Ga is a value of less than 5 and a value exceeding 5. From the standpoint of the stability of the crystal structure, the parameter k is preferably a value in a range of 0.95 or more and 1.05 or less (0.95≤k≤1.05), more preferably in a range of 0.98 or more and 1.02 or less (0.98≤k≤1.02), and further preferably in a range of 0.99 or more and 1.01 or less (0.99≤k≤1.01).

The rare earth aluminate fluorescent material may have a 50% cumulative particle diameter Dm2 in the volume based particle size distribution measured by the laser diffraction scattering particle size distribution measuring method in a range of 23 μm or more and 50 μm or less, preferably in a range of 23 μm or more and 45 μm or less, and more preferably in a range of 24 μm or more and 40 μm or less. The rare earth aluminate fluorescent material may have a 50% cumulative particle diameter Dm2 of 23 μm or more, i.e., a large particle diameter, and thus has a high light emission intensity. The rare earth aluminate fluorescent material may have a 50% cumulative particle diameter Dm2 of 50 μm or less, and thus has good handleability in the production of a light emitting device. The laser diffraction scattering particle size distribution measuring method is a method for measuring a particle size distribution by using scattering light of laser light, with which particles are irradiated, without discrimination of primary particles and secondary particles. The secondary particles mean particles that are formed through aggregation of primary particles.

The rare earth aluminate fluorescent material preferably has an average particle diameter Db measured by the Fisher sub-sieve sizer method (which may be hereinafter referred to as an “FSSS method”) in a range of 23 μm or more and 50 μm or less, more preferably in a range of 23 μm or more and 45 μm or less, and further preferably in a range of 24 μm or more and 40 μm or less. The rare earth aluminate fluorescent material preferably may have an average particle diameter Db measured by the FSSS method of 23 μm, i.e., a large particle diameter, and thus has a high light emission intensity. The rare earth aluminate fluorescent material may have an average particle diameter Db measured by the FSSS method of 50 μm or less, and thus has good handleability in the production of a light emitting device. The FSSS method is a one kind of a method of obtaining the particle diameter of particles by the air permeability method, and is a method of obtaining the particle diameter by measuring the specific surface of a particle area utilizing the flow resistance of air.

The rare earth aluminate fluorescent material may have a particle diameter ratio Dm2/Db of the 50% cumulative particle diameter Dm2 to the average particle diameter Db of 1.20 or less, preferably 1.19 or less, more preferably 1.18 or less, further preferably 1.17 or less, and particularly preferably 1.16 or less. A value of the particle diameter ratio Dm2/Db of the 50% cumulative particle diameter Dm2 to the average particle diameter Db that is closer to 1 means that the amount of the secondary particles formed through aggregation of the primary particles is smaller, and the amount of the primary particles is larger. The primary particles are particles that are formed through the growth of crystals of the rare earth aluminate fluorescent material, and the particle diameter ratio Dm2/Db that is closer to 1 means that the particles having a stable crystal structure are contained in a larger amount, and a higher light emission intensity can be obtained with a 50% cumulative particle diameter Dm2 of 23 μm or more and a particle diameter ratio Dm2/Db of 1.20 or less.

The rare earth aluminate fluorescent material preferably has an average circle equivalent diameter De in a range of 23 μm or more and 50 μm or less, more preferably in a range of 24 μm or more and 45 μm or less, and further preferably in a range of 25 μm or more and 40 μm or less. The circle equivalent diameter of the rare earth aluminate fluorescent material varies depending on the aggregation state and the shape of the fluorescent material. In the case where the fluorescent material is primary particles, and the shape of the fluorescent material is a shape close to a sphere, with an average circle equivalent diameter De within the aforementioned range, the rare earth aluminate fluorescent material has a large particle diameter, can have a high light emission intensity when applied to a light emitting device, and has good handleability in the production process.

The average circle equivalent diameter De of the rare earth aluminate fluorescent material may be measured in the following manner. An SEM image of the rare earth aluminate fluorescent material obtained with a scanning electron microscope (which may be hereinafter referred to as an “SEM”) is subjected to image analysis with an image analysis software (e.g., ImageJ), and 20 or more of the fluorescent material particles excluding the fluorescent material particles of which the number of pixels is 1 or less, the outer shape of each of which can be confirmed on the SEM image, are binarized. For each of 20 or more specimens binarized, the binarized particle shape is assumed to be a circle, and the diameter of the precise circle having the same area of the circle is designated as a circle equivalent diameter. Out of the measured specimens, 20 specimens are selected in descending order of the circle equivalent diameter, and the arithmetic average value of the circle equivalent diameters of the 20 specimens is designated as the average circle equivalent diameter De. “ImageJ” is an open-source public-domain image analysis software developed by National Institute of Health.

The average particle area Ap of the rare earth aluminate fluorescent material is preferably in a range of 265 μm² or more and 800 μm² or less, more preferably in a range of 300 μm² or more and 750 μm² or less, and further preferably in a range of 400 μm² or more and 700 μm² or less. The average particle area Ap of the rare earth aluminate fluorescent material varies depending on the aggregation state and the shape of the fluorescent material. In the case where the fluorescent material is primary particles, and the shape of the fluorescent material is a shape close to a sphere, with an average particle area Ap in a range of 265 μm² or more and 800 μm² or less, the rare earth aluminate fluorescent material has a large particle diameter, and has good handleability in the production process. The rare earth aluminate fluorescent material preferably has an average circle equivalent diameter De in a range of 23 μm or more and 50 μm or less and an average particle area Ap in a range of 265 μm² or more and 800 μm² or less from the standpoint of the light emission intensity and the handleability when applied to a light emitting device.

The average particle area Ap of the rare earth aluminate fluorescent material is a value that is measured in the following manner. An SEM image of the rare earth aluminate fluorescent material is subjected to image analysis with an image analysis software (e.g., ImageJ). In the image analysis of the SEM image of the rare earth aluminate fluorescent material, 20 or more of the fluorescent material particles excluding the fluorescent material particles of which the number of pixels is 1 or less, the outer shape of each of which can be confirmed on the SEM image, are binarized. For each of 20 or more specimens binarized, the product of the number of pixels constituting the binarized particle shape and the magnification is designated as the particle area of the fluorescent material particle. Out of the measured specimens, 20 specimens are selected from in descending order of the particle area, and the arithmetic average value of the particle areas of the 20 specimens is designated as the average particle area Ap.

### Light Emitting Device

The rare earth aluminate fluorescent material may be combined with a light emitting element, so as to constitute a light emitting device, in which the rare earth aluminate fluorescent material converts the wavelength of light emitted from the light emitting element, and the light emitting device emits mixed color light of the light emitted from the light emitting element and the light converted by the rare earth aluminate fluorescent material. The light emission peak wavelength of the light emitting element may be in a range of 350 nm or more and 500 nm or less or in a range of 380 nm or more and 485 nm or less, and is preferably in a range of 390 nm or more and 480 nm or less. Examples of the light emitting element used include a semiconductor light emitting element using a nitride semiconductor (In_{X}Al_{Y}Ga_{1-X-Y}N, wherein 0≤X, 0≤Y, and X+Y≤1). The use of a semiconductor light emitting element as the excitation light source can provide a light emitting device that has a high efficiency and a high linearity of the output with respect to the input, and has a high stability and a high resistance against a mechanical impact.

### EXAMPLES

The present disclosure will be described more specifically with reference to examples below. The present disclosure is not limited to the examples.

First Heat Treatment of Yttrium Oxide (Y₂O₃)

Yttrium oxide 1 that was not subjected to the first heat treatment, yttrium oxide 2 that was subjected to the first heat treatment at 1,000° C., yttrium oxide 3 that was subjected to the first heat treatment at 1,300° C., yttrium oxide 4 that was subjected to the first heat treatment at 1,400° C., and yttrium oxide 5 that was subjected to the first heat treatment at 1,500° C. were prepared. The first heat treatment was performed in such a manner that each yttrium oxide (Y₂O₃) was placed in an alumina crucible, and in the air, was heated to the corresponding first heat treatment temperature at a temperature raise rate of from 3° C./min to 7° C./min, and after reaching the first heat treatment temperature, retained at the first heat treatment temperature for 4 hours, followed by cooling to room temperature, so as to provide yttrium oxide subjected to the first heat treatment. The yttrium oxides before and after subjecting to the first heat treatment were measured for the crystallite diameter, the cumulative 50% particle diameter Dm1 in the volume based particle size distribution measured by a laser diffraction scattering particle size distribution measuring method, and the BET specific surface area, in the manners described later. The results are shown in Table 1 below.

### Crystallite Diameter

The yttrium oxides before the first heat treatment and the yttrium oxides after subjecting to the first heat treatment at corresponding temperatures were subjected to the XRD measurement (X-ray diffractometry, CuKα, tube voltage: 40 kV, tube current: 20 mA, scanning range: range of 10° or more and 70° or less (10°≤2θ≤70°), radiation source: CuKα, scanning axis: 2θ/θ, measurement method: FT, unit: count, step width: 0.02°, count time: 20°/min) using an X-ray diffractometer (Ultima IV, a trade name, manufactured by Rigaku Corporation). The measurement data were read by the analysis software using the fundamental parameter method, PDXL (manufactured by Rigaku Corporation), the XRD pattern of the crystal structure model was simulated by using the ICDD database, the XRD pattern obtained from the measurement and the XRD pattern obtained from the crystal structure model were fitted to each other, and the crystallite diameter of the specimen was obtained from the value obtained by using the Rietveld method, which was optimized by the least square method minimizing the residual error. ICDD card No. 01-089-05592 was used as the data for yttrium oxide, and depending on necessity ICDD card No. 01-071-0255 was used for the data for a single phase of Y₃Al₅O₁₂.

### Cumulative 50% Particle Diameter Dm1 and Dm2 By Laser Diffraction Scattering Particle Size Distribution Measuring Method

The yttrium oxides before the first heat treatment, the yttrium oxides after subjecting to the first heat treatment at the corresponding temperatures, and the rare earth aluminate fluorescent materials of Examples and Comparative Examples each were measured for the cumulative 50% particle diameter Dm1 from the small diameter side in the volume based particle size distribution and the cumulative 50% particle diameter Dm2 described later by using a laser diffraction particle size distribution measurement apparatus (Mastersizer 3000, manufactured by Malvern Panalytical, Ltd.).

### BET Specific Surface Area

The yttrium oxides before the first heat treatment and the yttrium oxides after subjecting to the first heat treatment at the corresponding temperatures each were measured for the BET specific surface area by the BET method by using an automatic surface area measurement apparatus (Macsorb, a trade name, manufactured by Mountech Co., Ltd.).

TABLE 1

| | | | Cumulative | |
|---|---|---|---|---|
| | Heat | | 50% particle | BET |
| | treatment | Crystallite | diameter | specific |
| | temperature | diameter | Dm1 | surface area |
| | (° C.) | (Å) | (μm) | (m²/g) |
| Yttrium oxide 1 | — | 1488 | 7.2 | 2.2 |
| Yttrium oxide 2 | 1000 | 1530 | 6.8 | 2.0 |
| Yttrium oxide 3 | 1300 | 2635 | 8.2 | 1.1 |
| Yttrium oxide 4 | 1400 | 3286 | 8.3 | 0.9 |
| Yttrium oxide 5 | 1500 | 2928 | 8.6 | 0.7 |

As shown in Table 1, yttrium oxides having a crystallite diameter of 1,500 Å or more, a cumulative 50% particle diameter Dm1 in the volume based particle size distribution of 6.5 μm or more, and a BET specific surface area of 2.1 m²/g or less were obtained by subjecting yttrium oxides to the first heat treatment in a range of 1,000° C. or more and 1,600° C. or less.

### Example 1

### Preparation of Raw Materials

Yttrium oxide 4 (Y₂O₃) having a crystallite diameter of 3,286 Å obtained through the first heat treatment, cerium oxide (CeO₂), aluminum oxide (Al₂O₃), and gallium oxide (Ga₂O₃) were used as raw materials, and the raw materials were weighed to make the charged composition shown in Table 2 below. Specifically, the raw materials were prepared by weighing the materials to make Y:Ce:Al:Ga=2.960:0.04:2.55:2.60. Barium fluoride (BaF₂) as the flux was added thereto in an amount of 3.0% by mass based on the total amount of the raw materials as 100% by mass to provide a mixture, and the raw materials were mixed with a ball mill to provide a mixture. A molar ratio of Ce in the raw material is represented by the product of 3 and the parameter n, the parameter n is 0.04/3. A molar ratio of Ga in the raw material represented by the product of the parameter m, the parameter k and 5, and the parameter m is 2.60/5k and the parameter k is 1.03.

### Second Heat Treatment

The resulting mixture was placed in an alumina crucible, and in a reducing atmosphere, subjected to the second heat treatment at 1,465° C. for 10 hours to provide a calcined product.

### Dispersion Treatment

The resulting calcined product, alumina balls as a dispersion medium, and pure water were placed in a vessel, and dispersed by rotating the vessel for 15 hours. Thereafter, coarse particles were removed by wet sieving. Subsequently, fine particles were removed by sedimentation classification.

### Acid Cleaning Treatment

The calcined product obtained by the sedimentation classification was acid-cleaned with a hydrochloric acid aqueous solution having a concentration of hydrochloric acid of 17% by mass, then washed with water, and separated and dried, so as to provide the calcined product after the acid cleaning treatment as a rare earth aluminate fluorescent material of Example 1.

### Example 2

A rare earth aluminate fluorescent material was obtained in the same manner as in Example 1 except that the raw materials were prepared by weighing the materials to make Y:Ce:Al:Ga=2.950:0.05:3.15:2.00. A molar ratio of Ce in the raw material is represented by the product of 3 and the parameter n, the parameter n is 0.05/3. A molar ratio of Ga in the raw material represented by the product of the parameter m, the parameter k and 5, and the parameter m is 2.00/5k and the parameter k is 1.03.

### Example 3

A rare earth aluminate fluorescent material was obtained in the same manner as in Example 1 except that the raw materials were prepared by weighing the materials to make Y:Ce:Al:Ga=2.942:0.058:3.35:1.80. A molar ratio of Ce in the raw material is represented by the product of 3 and the parameter n, the parameter n is 0.058/3. A molar ratio of Ga in the raw material represented by the product of the parameter m, the parameter k and 5, and the parameter m is 1.80/5k and the parameter k is 1.03.

### Example 4

A rare earth aluminate fluorescent material was obtained in the same manner as in Example 1 except that the raw materials were prepared by weighing the materials to make Y:Ce:Al:Ga=2.955:0.045:3.5:1.50, and barium fluoride (BaF₂) as the flux was added thereto in an amount of 4.0% by mass based on the total amount of the raw materials as 100% by mass to provide a mixture. A molar ratio of Ce in the raw material is represented by the product of 3 and the parameter n, the parameter n is 0.045/3. A molar ratio of Ga in the raw material represented by the product of the parameter m, the parameter k and 5, and the parameter m is 1.50/5k and the parameter k is 1.00.

### Example 5

A rare earth aluminate fluorescent material was obtained in the same manner as in Example 1 except that the raw materials were prepared by weighing the materials to make Y:Ce:Al:Ga=2.955:0.045:3.5:1.50, and barium fluoride (BaF₂) as the flux was added thereto in an amount of 5.0% by mass based on the total amount of the raw materials as 100% by mass to provide a mixture.

### Example 6

A rare earth aluminate fluorescent material was obtained in the same manner as in Example 1 except that the raw materials were prepared by weighing the materials to make Y:Ce:Al:Ga=2.955:0.045:3.5:1.50, and barium fluoride (BaF₂) as the flux was added thereto in an amount of 6.0% by mass based on the total amount of the raw materials as 100% by mass to provide a mixture.

### Example 7

A rare earth aluminate fluorescent material was obtained in the same manner as in Example 1 except that the raw materials were prepared by weighing the materials to make Y:Ce:Al:Ga=2.955:0.045:3.5:1.50, and barium fluoride (BaF₂) as the flux was added thereto in an amount of 7.0% by mass based on the total amount of the raw materials as 100% by mass to provide a mixture.

### Example 8

A rare earth aluminate fluorescent material was obtained in the same manner as in Example 1 except that the raw materials were prepared by weighing the materials to make Y:Ce:Al:Ga=2.955:0.045:4.05:1.13. A molar ratio of Ce in the raw material is represented by the product of 3 and the parameter n, the parameter n is 0.045/3. A molar ratio of Ga in the raw material represented by the product of the parameter m, the parameter k and 5, and the parameter m is 1.13/5k and the parameter k is 1.036.

### Example 9

A rare earth aluminate fluorescent material was obtained in the same manner as in Example 1 except that the raw materials were prepared by weighing the materials to make Y:Ce:Al:Ga=2.955:0.045:4.05:1.13, and barium fluoride (BaF₂) as the flux was added thereto in an amount of 4.0% by mass based on the total amount of the raw materials as 100% by mass to provide a mixture.

### Example 10

A rare earth aluminate fluorescent material was obtained in the same manner as in Example 1 except that the raw materials were prepared by weighing the materials to make Y:Ce:Al:Ga=2.955:0.045:4.05:1.13, and barium fluoride (BaF₂) as the flux was added thereto in an amount of 5.0% by mass based on the total amount of the raw materials as 100% by mass to provide a mixture.

### Example 11

A rare earth aluminate fluorescent material was obtained in the same manner as in Example 1 except that the raw materials were prepared by weighing the materials to make Y:Ce:Al:Ga=2.955:0.045:4.05:1.13, and barium fluoride (BaF₂) as the flux was added thereto in an amount of 6.0% by mass based on the total amount of the raw materials as 100% by mass to provide a mixture.

### Example 12

A rare earth aluminate fluorescent material was obtained in the same manner as in Example 1 except that yttrium oxide 2 (Y₂O₃) having a crystallite diameter of 1,530 Å obtained through the first heat treatment was used, the raw materials were prepared by weighing the materials to make Y:Ce:Al:Ga=2.942:0.058:3.35:1.80, and barium fluoride (BaF₂) as the flux was added thereto in an amount of 4.0% by mass based on the total amount of the raw materials as 100% by mass to provide a mixture. A molar ratio of Ce in the raw material is represented by the product of 3 and the parameter n, the parameter n is 0.058/3. A molar ratio of Ga in the raw material represented by the product of the parameter m, the parameter k and 5, and the parameter m is 1.80/5k and the parameter k is 1.03.

### Example 13

A rare earth aluminate fluorescent material was obtained in the same manner as in Example 1 except that yttrium oxide 3 (Y₂O₃) having a crystallite diameter of 2,635 Å obtained through the first heat treatment was used, the raw materials were prepared by weighing the materials to make Y:Ce:Al:Ga=2.942:0.058:3.35:1.80, and barium fluoride (BaF₂) as the flux was added thereto in an amount of 4.0% by mass based on the total amount of the raw materials as 100% by mass to provide a mixture.

### Example 14

A rare earth aluminate fluorescent material was obtained in the same manner as in Example 1 except that the raw materials were prepared by weighing the materials to make Y:Ce:Al:Ga=2.942:0.058:3.35:1.80, and barium fluoride (BaF₂) as the flux was added thereto in an amount of 4.0% by mass based on the total amount of the raw materials as 100% by mass to provide a mixture.

### Example 15

A rare earth aluminate fluorescent material was obtained in the same manner as in Example 1 except that yttrium oxide 5 (Y₂O₃) having a crystallite diameter of 2,928 Å obtained through the first heat treatment was used, the raw materials were prepared by weighing the materials to make Y:Ce:Al:Ga=2.942:0.058:3.35:1.80, and barium fluoride (BaF₂) as the flux was added thereto in an amount of 4.0% by mass based on the total amount of the raw materials as 100% by mass to provide a mixture.

### Comparative Example 1

A rare earth aluminate fluorescent material was obtained in the same manner as in Example 1 except that yttrium oxide 1 (Y₂O₃) having a crystallite diameter of 1,488 Å that was not subjected to the first heat treatment was used.

### Comparative Example 2

A rare earth aluminate fluorescent material was obtained in the same manner as in Comparative Example 1 except that the raw materials were prepared by weighing the materials to make Y:Ce:Al:Ga=2.95:0.05:3.15:2.00. A molar ratio of Ce in the raw material is represented by the product of 3 and the parameter n, the parameter n is 0.05/3. A molar ratio of Ga in the raw material represented by the product of the parameter m, the parameter k and 5, and the parameter m is 2.00/5k and the parameter k is 1.03.

### Comparative Example 3

A rare earth aluminate fluorescent material was obtained in the same manner as in Comparative Example 1 except that the raw materials were prepared by weighing the materials to make Y:Ce:Al:Ga=2.942:0.058:3.35:1.80. A molar ratio of Ce in the raw material is represented by the product of 3 and the parameter n, the parameter n is 0.058/3. A molar ratio of Ga in the raw material represented by the product of the parameter m, the parameter k and 5, and the parameter m is 1.80/5k and the parameter k is 1.03.

### Comparative Example 4

### Preparation of Raw Materials

Yttrium oxide 1 (Y₂O₃) having a crystallite diameter of 1,488 Å that was not subjected to the first heat treatment, cerium oxide (CeO₂), aluminum oxide (Al₂O₃), and gallium oxide (Ga₂O₃) were used as raw materials, and the raw materials were prepared by weighing the materials to make Y:Ce:Al:Ga=2.960:0.04:2.55:2.60. Barium fluoride (BaF₂) as the flux was added thereto in an amount of 3.0% by mass based on the total amount of the raw materials as 100% by mass to provide a mixture, and the raw materials were mixed with a ball mill to provide a mixture. A molar ratio of Ce in the raw material is represented by the product of 3 and the parameter n, the parameter n is 0.04/3. A molar ratio of Ga in the raw material represented by the product of the parameter m, the parameter k and 5, and the parameter m is 2.60/5k and the parameter k is 1.03.

### Second Heat Treatment

The resulting mixture was placed in an alumina crucible, and in a reducing atmosphere, subjected to the second heat treatment at 1,600° C. for 10 hours to provide a calcined product.

### Dispersion Treatment

The resulting calcined product, alumina balls as a dispersion medium, and pure water were placed in a vessel, and dispersed by rotating the vessel for 15 hours. Thereafter, coarse particles were selectively taken out by dry sieving, so as to provide a rare earth aluminate fluorescent material of Comparative Example 4.

### Comparative Example 5

### Preparation of Raw Materials

A rare earth aluminate fluorescent material was obtained in the same manner as in Example 1 except that yttrium oxide 4 (Y₂O₃) having a crystallite diameter of 3,286 Å obtained through the first heat treatment, cerium oxide (CeO₂), aluminum oxide (Al₂O₃), and gallium oxide (Ga₂O₃) were used as raw materials, and the raw materials were prepared by weighing the materials to make Y:Ce:Al:Ga=2.942:0.058:3.35:1.80, so as to prepare a mixture. A molar ratio of Ce in the raw material is represented by the product of 3 and the parameter n, the parameter n is 0.058/3. A molar ratio of Ga in the raw material represented by the product of the parameter m, the parameter k and 5, and the parameter m is 1.80/5k and the parameter k is 1.03.

### Comparative Example 6

A rare earth aluminate fluorescent material was obtained in the same manner as in Example 1 except that yttrium oxide 4 (Y₂O₃) having a crystallite diameter of 3,286 Å obtained through the first heat treatment, cerium oxide (CeO₂), aluminum oxide (Al₂O₃), and gallium oxide (Ga₂O₃) were used as raw materials, the raw materials were prepared by weighing the materials to make Y:Ce:Al:Ga=2.942:0.058:3.35:1.80, and barium fluoride (BaF₂) as the flux was added thereto in an amount of 1.0% by mass based on the total amount of the raw materials as 100% by mass to provide a mixture, so as to prepare a mixture.

### Comparative Example 7

A rare earth aluminate fluorescent material was obtained in the same manner as in Comparative Example 1 except that yttrium oxide 4 (Y₂O₃) having a crystallite diameter of 3,286 Å obtained through the first heat treatment was used, the raw materials were prepared by weighing the materials to make Y:Ce:Al:Ga=2.942:0.058:3.35:1.80, and barium fluoride (BaF₂) as the flux was added thereto in an amount of 2.0% by mass based on the total amount of the raw materials as 100% by mass to provide a mixture, so as to prepare a mixture.

### Comparative Example 8

A rare earth aluminate fluorescent material was obtained in the same manner as in Example 1 except that yttrium oxide 4 (Y₂O₃) having a crystallite diameter of 3,286 Å obtained through the first heat treatment, cerium oxide (CeO₂), aluminum oxide (Al₂O₃), and gallium oxide (Ga₂O₃) were used as raw materials, and the raw materials were weighed to make the charged composition shown in Table 2 below. Specifically, the raw materials were prepared by weighing the materials to make Y:Ce:Al:Ga=2.960:0.040:2.55:2.60, and barium fluoride (BaF₂) as the flux was added thereto in an amount of 8.0% by mass based on the total amount of the raw materials as 100% by mass to provide a mixture, so as to prepare the mixture. A molar ratio of Ce in the raw material is represented by the product of 3 and the parameter n, the parameter n is 0.040/3. A molar ratio of Ga in the raw material represented by the product of the parameter m, the parameter k and 5, and the parameter m is 2.60/5k and the parameter k is 1.03.

### Comparative Example 9

A rare earth aluminate fluorescent material was obtained in the same manner as in Comparative Example 1 except that the raw materials were prepared by weighing the materials to make Y:Ce:Al:Ga=2.955:0.045:4.05:1.13. A molar ratio of Ce in the raw material is represented by the product of 3 and the parameter n, the parameter n is 0.045/3. A molar ratio of Ga in the raw material represented by the product of the parameter m, the parameter k and 5, and the parameter m is 1.13/5k and the parameter k is 1.036.

### Comparative Example 10

A rare earth aluminate fluorescent material was obtained in the same manner as in Comparative Example 1 except that the raw materials were prepared by weighing the materials to make Y:Ce:Al:Ga=2.942:0.058:3.35:1.80, and barium fluoride (BaF₂) as the flux was added thereto in an amount of 4.0% by mass based on the total amount of the raw materials as 100% by mass to provide a mixture, so as to prepare a mixture. A molar ratio of Ce in the raw material is represented by the product of 3 and the parameter n, the parameter n is 0.058/3. A molar ratio of Ga in the raw material represented by the product of the parameter m, the parameter k and 5, and the parameter m is 1.80/5k and the parameter k is 1.03.

The rare earth aluminate fluorescent materials of Examples and Comparative Examples each were subjected to the following analysis. The results are shown in Table 2.

### Average Particle Diameter (Db) By FSSS Method

For each of the rare earth aluminate fluorescent materials of Examples and Comparative Examples, by using Fisher Sub-Sieve Sizer Model 95 (manufactured by Fisher Scientific International, Inc.), under an environment of a temperature of 25° C. and a relative humidity of 70%, a specimen in an amount of 1 cm³ was collected therefrom and packed in a dedicated tube container, then dry air was flowed through the container at a constant pressure, and the specific surface area was red from the differential pressure, from which the average particle diameter by the FSSS method was calculated.

### Particle Diameter Ratio Dm2/Db

For each of the rare earth aluminate fluorescent materials of Examples and Comparative Examples, the particle diameter ratio Dm2/Db of the 50% cumulative particle diameter Dm2 in the volume based particle size distribution measured by a laser diffraction scattering particle size distribution measuring method to the average particle diameter Db by the FSSS method was calculated.

### Compositional Analysis

The resulting fluorescent material was measured for the mass percentages (% by mass) of the elements constituting the rare earth aluminate fluorescent material (i.e., Y, Lu, Ce, Al, Ga, and O) by the inductively coupled plasma-atomic emission spectroscopy (ICP-AES) (Model name: Optima 8300, manufactured by PerkinElmer, Inc.), and the molar ratios of the elements were calculated from the mass percentages of the elements. The molar ratios of Y, Ce, Al, Ga, and O shown in Table 2 are values that are calculated based on the total molar ratio of Y and Ce of 3. The value obtained by dividing the molar ratio of Ce by the total molar ratio of Y and Ce of 3 was designated as the parameter n. The value obtained by dividing the molar ratio of Ga by the product of the total molar ratio of Al and Ga, 5, and the parameter k was designated as the parameter m. 5 is the coefficient of the parameter k, and the product of the parameter k and 5 is the total molar ratio of Al and Ga.

### Light Emission Intensity

The rare earth aluminate fluorescent materials of Examples and Comparative Examples each were measured for the light emission spectrum at room temperature (25° C.±5° C.) by irradiating the fluorescent material with light having an excitation wavelength of 450 nm with a quantum efficiency measuring apparatus (Model Name: QE-2000, manufactured by Otsuka Electronics Co., Ltd.), and assuming that the wavelength where the light emission spectrum was maximized was designated as the light emission peak wavelength (nm), the light emission intensity at the light emission peak wavelength was measured. The relative light emission intensity was calculated for each of the combinations of Example 1 and Comparative Example 1, Example 2 and Comparative Example 2, Examples 3 to 7 and Comparative Examples 3 to 8, Examples 8 to 11 and Comparative Example 9, and Examples 12 to 15 and Comparative Example 10. Specifically, the relative light emission intensity of Example 1 was obtained assuming that the light emission intensity of Comparative Example 1 was 100%. The relative light emission intensity of Example 2 was obtained assuming that the light emission intensity of Comparative Example 2 was 100%. The relative light emission intensities of Examples 3 to 7 and Comparative Examples 4 to 8 were obtained assuming that the light emission intensity of Comparative Example 3 was 100%. The relative light emission intensities of Examples 8 to 11 were obtained assuming that the light emission intensity of Comparative Example 9 was 100%. The relative light emission intensities of Examples 12 to 15 were obtained assuming that the light emission intensity of Comparative Example 10 was 100%.

### Average Circle Equivalent Diameter De

For each of the rare earth aluminate fluorescent materials of Examples and Comparative Examples, the SEM image obtained with a scanning electron microscope (SEM) was subjected to image analysis with an image analysis software (product name: ImageJ, manufactured by National Institute of Health). 20 or more of the fluorescent material particles excluding the fluorescent material particles with a pixel number of 1 or less, the outer shape of each of which was confirmed on the SEM image, were binarized, and for each of 20 or more specimens binarized, the binarized particle shape was assumed to be a circle, and the diameter of the precise circle having the same area of the circle was designated as a circle equivalent diameter. Out of the measured specimens, 20 specimens were selected in descending order of the circle equivalent diameter, and the arithmetic average value of the circle equivalent diameters of the 20 specimens was designated as the average circle equivalent diameter De.

### Average Particle Area Ap

For each of the rare earth aluminate fluorescent materials of Examples and Comparative Examples, the SEM image obtained with a scanning electron microscope was subjected to image analysis with an image analysis software (product name: ImageJ, manufactured by National Institute of Health). 20 or more of the fluorescent material particles excluding the fluorescent material particles with a pixel number of 1 or less, the outer shape of each of which was confirmed on the SEM image, were binarized, and for each of 20 or more specimens binarized, the product of the number of pixels constituting the binarized particle shape and the magnification was designated as the particle area of the fluorescent material particle. Out of the measured specimens, 20 specimens were selected in descending order of the particle area, and the arithmetic average value of the particle areas of the 20 specimens was designated as the average particle area Ap.

TABLE 2

| | Raw material (Y₂O₃) | | | | | | | |
|---|---|---|---|---|---|---|---|---|
| | First heat | | Cumulative | | Mixture | | | |
| | treatment | Crystallite | 50% particle | BET specific | | Ce | Ga | |
| | temperature | diameter | diameter Dm1 | surface area | | Parameter | Parameter | Parameter |
| | (° C.) | (Å) | (μm) | (m²/g) | Charged composition | n | m | k |
| Comparative | — | 1488 | 7.2 | 2.2 | Y_{2.960}Ce_{0.040}Al_{2.550}Ga_{2.60}O₁₂ | 0.013 | 0.520 | 1.030 |
| Example 1 | | | | | | | | |
| Example 1 | 1400 | 3286 | 8.3 | 0.9 | | | | |
| Comparative | — | 1488 | 7.2 | 2.2 | Y_{2.950}Ce_{0.050}Al_{3.150}Ga_{2.00}O₁₂ | 0.017 | 0.400 | |
| Example 2 | | | | | | | | |
| Example 2 | 1400 | 3286 | 8.3 | 0.9 | | | | |
| Comparative | — | 1488 | 7.2 | 2.2 | Y_{2.942}Ce_{0.058}Al_{3.350}Ga_{1.80}O₁₂ | 0.019 | 0.360 | |
| Example 3 | | | | | | | | |
| Comparative | — | 1488 | 7.2 | 2.2 | Y_{2.960}Ce_{0.040}Al_{2.550}Ga_{2.60}O₁₂ | 0.013 | 0.520 | |
| Example 4 | | | | | | | | |
| Comparative | 1400 | 3286 | 8.3 | 0.9 | Y_{2.942}Ce_{0.058}Al_{3.350}Ga_{1.80}O₁₂ | 0.019 | 0.360 | |
| Example 5 | | | | | | | | |
| Comparative | | | | | | | | |
| Example 6 | | | | | | | | |
| Comparative | | | | | | | | |
| Example 7 | | | | | | | | |
| Example 3 | | | | | | | | |
| Example 4 | | | | | Y_{2.955}Ce_{0.045}Al_{3.500}Ga_{1.50}O₁₂ | 0.015 | 0.300 | 1.000 |
| Example 5 | | | | | | | | |
| Example 6 | | | | | | | | |
| Example 7 | | | | | | | | |
| Comparative | | | | | Y_{2.960}Ce_{0.040}Al_{2.550}Ga_{2.60}O₁₂ | 0.013 | 0.893 | 1.046 |
| Example 8 | | | | | | | | |
| Comparative | — | 1488 | 7.2 | 2.2 | Y_{2.955}Ce_{0.045}Al_{4.050}Ga_{1.130}O₁₂ | 0.015 | 0.226 | 1.036 |
| Example 9 | | | | | | | | |
| Example 8 | 1400 | 3286 | 8.3 | 0.9 | | | | |
| Example 9 | | | | | | | | |
| Example 10 | | | | | | | | |
| Example 11 | | | | | | | | |
| Comparative | — | 1488 | 7.2 | 2.2 | Y_{2.942}Ce_{0.058}Al_{3.350}Ga_{1.80}O₁₂ | 0.019 | 0.360 | 1.030 |
| Example 10 | | | | | | | | |
| Example 12 | 1000 | 1530 | 6.8 | 2.0 | | | | |
| Example 13 | 1300 | 2635 | 8.2 | 1.1 | | | | |
| Example 14 | 1400 | 3286 | 8.3 | 0.9 | | | | |
| Example 15 | 1500 | 2928 | 8.6 | 0.7 | | | | |

| | Mixture | | Relative | Average | Cumulative | | | Circle |
|---|---|---|---|---|---|---|---|---|
| | Flux | Second heat | light | particle | 50% particle | Particle | Average | equivalent |
| | (BaF₂) | treatment | emission | diameter | diameter | diameter | particle | diameter |
| | (% by | temperature | intensity | Db | Dm2 | ratio | area Ap | De |
| | mass) | (° C.) | (%) | (μm) | (μm) | Dm2/Db | (μm²) | (μm) |
| Comparative | 3.0 | 1465 | 100.0 | 19.5 | 19.8 | 1.01 | — | — |
| Example 1 | | | | | | | | |
| Example 1 | | | 105.4 | 28.5 | 30.2 | 1.06 | — | — |
| Comparative | 3.0 | 1465 | 100.0 | 19.0 | 21.6 | 1.14 | — | — |
| Example 2 | | | | | | | | |
| Example 2 | | | 103.4 | 31.5 | 34.0 | 1.08 | — | — |
| Comparative | 3.0 | 1465 | 100.0 | 19.0 | 21.0 | 1.11 | 194.6 | 20.26 |
| Example 3 | | | | | | | | |
| Comparative | 3.0 | 1600 | 96.7 | 28.0 | 34.0 | 1.21 | 667.9 | 29.63 |
| Example 4 | | | | | | | | |
| Comparative | 0.0 | 1465 | 77.7 | 3.8 | 10.0 | 2.66 | — | — |
| Example 5 | | | | | | | | |
| Comparative | 1.0 | | 91.8 | 5.9 | 12.0 | 2.03 | — | — |
| Example 6 | | | | | | | | |
| Comparative | 2.0 | | 86.2 | 11.4 | 26.9 | 2.36 | — | — |
| Example 7 | | | | | | | | |
| Example 3 | 3.0 | | 103.9 | 31.0 | 31.7 | 1.02 | 592.3 | 27.92 |
| Example 4 | 4.0 | | 102.2 | 31.0 | 30.5 | 0.99 | — | — |
| Example 5 | 5.0 | | 102.2 | 29.5 | 29.2 | 0.99 | — | — |
| Example 6 | 6.0 | | 103.5 | 27.5 | 26.7 | 0.97 | — | — |
| Example 7 | 7.0 | | 101.5 | 25.0 | 25.1 | 1.01 | — | — |
| Comparative | 8.0 | | 100.7 | 22.0 | 22.6 | 1.03 | 261.9 | 22.16 |
| Example 8 | | | | | | | | |
| Comparative | 3.0 | 1465 | 100.0 | 20.0 | 22.4 | 1.12 | — | — |
| Example 9 | | | | | | | | |
| Example 8 | 3.0 | | 101.5 | 27.0 | 31.3 | 1.16 | — | — |
| Example 9 | 4.0 | | 103.2 | 28.5 | 32.7 | 1.15 | — | — |
| Example 10 | 5.0 | | 103.0 | 31.5 | 32.5 | 1.03 | — | — |
| Example 11 | 6.0 | | 102.3 | 26.5 | 29.3 | 1.11 | — | — |
| Comparative | 4.0 | 1465 | 100.0 | 19.0 | 18.2 | 0.96 | — | — |
| Example 10 | | | | | | | | |
| Example 12 | 4.0 | | 100.5 | 24.5 | 24.1 | 0.98 | — | — |
| Example 13 | 4.0 | | 103.1 | 28.5 | 29.1 | 1.02 | — | — |
| Example 14 | 4.0 | | 102.1 | 31.0 | 30.5 | 0.99 | — | — |
| Example 15 | 4.0 | | 99.9 | 33.0 | 34.3 | 1.04 | — | — |

As shown by Examples 1 to 15 in Table 2, the rare earth aluminate fluorescent materials formed by using, as the raw material, yttrium oxide having a crystallite diameter of 1,500 Å or more obtained through the first heat treatment in a range of 1,000° C. or more and 1,600° C. or less had a large particle diameter, i.e., a cumulative 50% particle diameter Dm2 of 23 μm or more, and had a large relative light emission intensity. As shown by Examples 1 to 15, the rare earth aluminate fluorescent materials formed by using, as the raw material, yttrium oxide having a crystallite diameter of 1,500 Å or more obtained through the first heat treatment in a range of 1,000° C. or more and 1,600° C. or less had a particle diameter ratio Dm2/Db of 1.2 or more, which meant a large proportion of primary particles, and contained a large amount of particles having a stable crystal structure. As shown by Example 3, the rare earth aluminate fluorescent material formed by using, as the raw material, yttrium oxide having a crystallite diameter of 1,500 Å or more obtained through the first heat treatment in a range of 1,000° C. or more and 1,600° C. or less had a large average circle equivalent diameter De of 23 μm or more, and had a large average particle area Ap of 400 μm² or more.

Comparative Examples 1 to 4, 9, and 10 each used yttrium oxide that was not subjected to the first heat treatment, and except for Comparative Example 4, the cumulative 50% particle diameter Dm2 was as small as less than 23 μm, and the relative light emission intensity was small. Comparative Example 4 had a large cumulative 50% particle diameter Dm2 exceeding 23 μm, but the particle diameter ratio Dm2/Db was as large as exceeding 1.20, which meant a large proportion of secondary particles formed through aggregation of primary particles, and the light emission intensity was lowered.

In Comparative Examples 5 to 7, even though yttrium oxide obtained through the first heat treatment was used as the raw material, the crystal growth was not accelerated, the particle diameter ratio Dm2/Db of the resulting rare earth aluminate fluorescent material was as large as exceeding 1.2, which meant a large proportion of secondary particles formed through aggregation of primary particles, and the light emission intensity was lowered since the amount of the compound as the flux contained in the mixture was less than 2.5% by mass based on the total amount of the raw materials. In Comparative Example 8, even though yttrium oxide obtained through the first heat treatment was used as the raw material, the cumulative 50% particle diameter Dm2 of the resulting rare earth aluminate fluorescent material was decreased to less than 23 μm due to the fluctuation in progress of the solid state reaction since the amount of the compound as the flux contained in the mixture was as large as exceeding 7.5% by mass based on the total amount of the raw materials.

The rare earth aluminate fluorescent material according to one embodiment of the present disclosure may be combined with a light emitting element, such as LED and LD, and can be applied to a light emitting device for an automobile or general illumination, a backlight source of a liquid crystal display device, and a light source device for a projector.

The invention claimed is:

1. A method for producing a rare earth aluminate fluorescent material, comprising:
subjecting a compound containing Ln that is at least one rare earth element selected from the group consisting of Y, La, Lu, Gd, and Tb, to a first heat treatment at a temperature in a range of 1,000° C. or more and 1,600° C. or less;
preparing a raw material containing an oxide containing Ln having a crystallite diameter of 1,500 Å or more obtained through the first heat treatment, a compound containing Ce, a compound containing Al, and optionally a compound containing Ga, having a chemical composition having a total molar ratio of Ln and Ce of 3, a total molar ratio of Al and Ga of a product of 5 and a parameter k of 0.95 or more and 1.05 or less, a molar ratio of Ce of a product of 3 and a parameter n of 0.005 or more and 0.050 or less, and a molar ratio of Ga of a product of a parameter m of 0 or more and 0.6 or less, the parameter k, and 5;
providing a mixture containing the raw material and a compound containing at least one element selected from the group consisting of Ba, Sr, Ca, Mg, and Mn as a flux in an amount of 2.5% by mass or more and 7.5% by mass or less based on a total amount of the raw material; and
subjecting the mixture to a second heat treatment at a temperature in a range of 1,400° C. or more and 1,800° C. or less to provide a calcined product.

2. The method for producing a rare earth aluminate fluorescent material according to claim 1, wherein the temperature at which the first heat treatment is performed is in a range of 1,200° C. or more and 1,500° C. or less.

3. The method for producing a rare earth aluminate fluorescent material according to claim 1, wherein the oxide containing Ln has a crystallite diameter of 1,500 Å or more and 3,500 Å or less.

4. The method for producing a rare earth aluminate fluorescent material according to claim 1, wherein the oxide containing Ln has a cumulative 50% particle diameter Dm1 in a volume based particle size distribution measured by a laser diffraction scattering particle size distribution measuring method of 6.5 μm or more.

5. The method for producing a rare earth aluminate fluorescent material according to claim 1, wherein the oxide containing Ln has a specific surface area measured by a BET method in a range of 0.5 m²/g or more and 2.1 m²/g or less.

6. The method for producing a rare earth aluminate fluorescent material according to claim 1, wherein the mixture is provided by preparing the raw material having a total molar ratio of the rare earth element Ln and Ce of 3, a total molar ratio of Al and Ga of a product of 5 and a parameter k of 0.95 or more and 1.05 or less, a molar ratio of Ce of a product of 3 and a parameter n of 0.005 or more and 0.050 or less, and a molar ratio of Ga of a product of a parameter m of 0.05 or more and 0.6 or less, the parameter k, and 5.

7. The method for producing a rare earth aluminate fluorescent material according to claim 1, wherein the resulting rare earth aluminate fluorescent material has a chemical composition represented by the following formula (I):
(Ln₁₋ₙCeₙ)₃(Al₁₋ₘGaₘ)₅ₖO₁₂ (I)
wherein in the formula (I), Ln represents at least one rare earth element selected from the group consisting of Y, La, Lu, Gd, and Tb, and k, m, and n satisfy 0.95≤k≤1.05, 0≤m≤0.6, and 0.005≤n≤0.050.

8. The method for producing a rare earth aluminate fluorescent material according to claim 7, wherein in the formula (I), m satisfies 0.05≤m≤0.6.

9. A rare earth aluminate fluorescent material comprising Ln that is at least one rare earth element selected from the group consisting of Y, La, Lu, Gd, and Tb, Ce, Al, O, and optionally Ga; having a chemical composition having a total molar ratio of the rare earth element Ln and Ce of 3, a molar ratio of Ce of a product of 3 and a parameter n of 0.005 or more and 0.050 or less, a total molar ratio of Al and Ga of a product of 5 and a parameter k of 0.95 or more and 1.05 or less, a molar ratio of Ga of a product of a parameter m of 0 or more and 0.6 or less, the parameter k, and 5, and a molar ratio of 0 of 12, per 1 mol of the chemical composition; having a cumulative 50% particle diameter Dm2 in a volume based particle size distribution measured by a laser diffraction scattering particle size distribution measuring method in a range of 23 μm or more and 50 μm or less; and having a particle diameter ratio Dm2/Db of the cumulative 50% particle diameter Dm2 to an average particle diameter Db measured by a Fisher sub-sieve sizer method of 1.2 or less.

10. The rare earth aluminate fluorescent material according to claim 9, wherein the chemical composition has a molar ratio of Ga of a product of a parameter m of 0.05 or more and 0.6 or less, the parameter k, and 5.

11. The rare earth aluminate fluorescent material according to claim 9, wherein the rare earth aluminate fluorescent material has a chemical composition represented by the following formula (I):
(Ln₁₋ₙCeₙ)₃(Al₁₋ₘGaₘ)₅ₖO₁₂ (I)
wherein in the formula (I), Ln represents at least one rare earth element selected from the group consisting of Y, La, Lu, Gd, and Tb, and k, m, and n satisfy 0.95≤k≤1.05, 0≤m≤0.6, and 0.005≤n≤0.050.

12. The rare earth aluminate fluorescent material according to claim 11, wherein in the formula (I), m satisfies 0.05≤m≤0.6.

13. A light emitting device comprising the rare earth aluminate fluorescent material according to claim 9, and a light emitting element having a light emission peak wavelength in a range of 380 nm or more and 485 nm or less.
